(19) United States
(12) Patent Application Publication
(10) Pub. No.: US 2020/0389987 A1
(43) Pub. Date: Dec. 10, 2020

(54) IMAGE DISPLAY DEVICE AND MULTI-DISPLAY SYSTEM

(71) Applicant: Mitsubishi Electric Corporation, Tokyo (JP)

(72) Inventors: Naoki KANNO, Tokyo (JP); Shota KANEKO, Tokyo (JP)

(73) Assignee: Mitsubishi Electric Corporation, Tokyo (JP)

(21) Appl. No.: 16/324,033

(22) PCT Filed: Dec. 15, 2017
(86) PCT No.: PCT/JP2017/045015

§ 371 Date: Feb. 7, 2019

(51) Int. Cl. H05K 5/02; H05K 5/00; H01L 27/15; H01L 33/48; G09F 19/22

(52) U.S. Cl. CPC H05K 5/0217; H05K 5/0017; H05K 5/0021; G09F 9/33; H01L 33/483; G09F 19/22; H01L 27/156

(57) ABSTRACT

The object is to provide a technology capable of reducing level difference between display screens of image display devices. An image display device includes an adjustment unit that adjusts a position of an LED module while the LED module is temporarily fixed to a housing frame, and a fixing unit that fixes, to the housing frame, the LED module that is temporarily fixed to the housing frame. A turning axis of an adjustment screw of the adjustment unit and a turning axis of a fixing screw of the fixing unit are arranged coaxially.

### TECHNICAL FIELD

The present invention relates to an image display device, and to a multi-display system including the image display device.

### BACKGROUND ART

A multi-display system has hitherto been proposed. The multi-display system includes a plurality of image display devices in which a plurality of display elements such as light emitting diodes (LEDs) are disposed, and displays an image on a large screen obtained by combining screens of the plurality of image display devices. The multi-display system is often used in advertisement displays indoors as well as outdoors, owing to enhanced performance and reduced costs of the display elements. The multi-display system was formerly mainly used for displaying a moving image, such as a natural image and animation.

However, the development of further narrowing pixel pitches due to downsized display elements resulted in achievement of appropriate display quality even at a short visible distance. Consequently, the multi-display system came into use as an image display for a computer to be used in a meeting room, used for a monitoring purpose, etc., as well as the indoor advertisement display, for example. Particularly, some multi-display systems used for a monitoring purpose display a computer image that nearly is a still image.

As the multi-display systems, surface mount devices (SMD), in which a small LED display module is mounted on a substrate, were mainly used, and thus large multi-display systems having a pixel pitch of 3 mm or more were formed. Further, the LED display module was formed by mounting LED display elements inside the cavities of a molded article, which is molded using ceramic, resin, or the like, and then fixing the LED display elements using a sealing resin.

In recent years, however, under circumstances of reduced costs and improved resolutions of LED display elements with use of a high-density packaging component, the market has been introduced with large multi-display systems, in which a plurality of image display devices including LED display elements having a pixel pitch of approximately from 1 to 2 mm are arrayed in a tile-like pattern. Note that, in Patent Document 1 and Patent Document 2, for example, a configuration and a retaining method of an image display device of a multi-display system are disclosed.

### PRIOR ART DOCUMENTS

### Patent Documents

Patent Document 1: Japanese Patent Application Laid-Open No. 2007-248498

Patent Document 2: Japanese Patent Application Laid-Open No. 2017-62454

### SUMMARY

### Problem to be Solved by the Invention

In a multi-display system in which a plurality of image display devices each having a display screen are arrayed, level difference between display screens of the plurality of image display devices in a front and rear direction may be sometimes noticeable on the display screens. In this manner, uniformity of surface flatness in the display screen surfaces of a plurality of image display devices has a great impact on image quality. Therefore, retaining and fixing of each image display unit is essential for the multi-display system. However, Patent Document 1 and Patent Document 2 do not consider elimination of the level difference between display screens of the image display devices.

In view of the above, the present invention has been made in order to solve the problems as above, and has an object to provide a technology capable of reducing level difference between display screens of image display devices.

### Means to Solve the Problem

An image display device according to the present invention includes an image display module, a frame, an adjustment unit, and a fixing unit. Display elements are disposed on the image display module. The image display module is to be fixed to the frame. The adjustment unit adjusts a position of the image display module in a direction perpendicular to a display screen of the image display module while the image display module is temporarily fixed to the frame. The fixing unit fixes, to the frame, the image display module that is temporarily fixed to the frame. The adjustment unit includes an adjustment screw that is turned during adjustment. The fixing unit includes a fixing screw that is turned during fixing. A turning axis of the adjustment screw and a turning axis of the fixing screw are arranged coaxially.

### Effects of the Invention

According to the present invention, the adjustment unit and the fixing unit are included, and therefore level difference between the display screens of the image display devices can be reduced.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a perspective view showing a schematic configuration of a multi-display system according to a first embodiment.

FIG. 2 is a perspective view showing a schematic configuration of an image display device according to the first embodiment.

FIG. 3 is a perspective view showing a rear configuration of the image display device according to the first embodiment.

FIG. 4 is a perspective view showing a configuration of a fixing screw according to the first embodiment.

FIG. 5 is a cross-sectional view showing a structure of an adjustment unit and a fixing unit according to the first embodiment.

FIG. 6 is a cross-sectional view for illustrating fixing of the fixing screw according to the first embodiment.

FIG. 7 is a perspective view showing a rear configuration of an image display device according to a second embodiment.

FIG. 8 is a cross-sectional view showing a structure of an adjustment unit and a fixing unit according to the second embodiment.

FIG. 9 is a cross-sectional view for illustrating fixing of a fixing screw according to the second embodiment.

### DESCRIPTION OF EMBODIMENTS

### First Embodiment

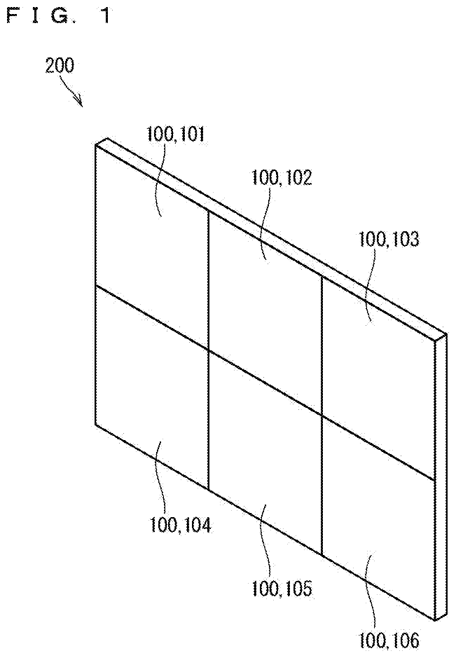

FIG. 1 is a perspective view showing a schematic configuration of a multi-display system 200 according to a first embodiment of the present invention. As shown in FIG. 1, the multi-display system 200 includes a plurality of image display devices 101 to 106 for displaying an image that are disposed in a matrix pattern. In the following description, when the image display devices 101 to 106 are not distinguished, each of the image display devices is referred to as an image display device 100. The multi-display system 200 includes an assembled plurality of image display devices 100 that are fixed by a fixing member (not shown), and can display an image on a large screen that is obtained by combining display screens of the plurality of image display devices 100.

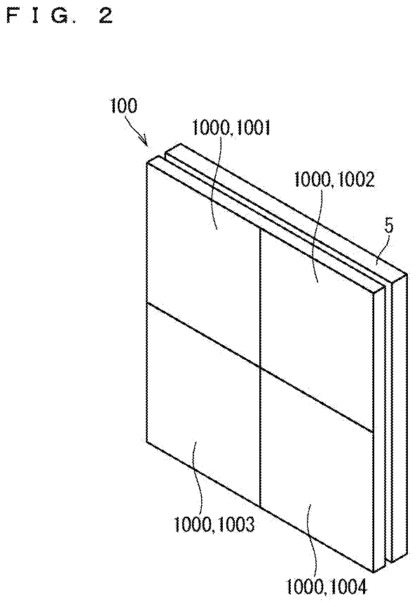

FIG. 2 is a perspective view showing a schematic configuration of the image display device 100. As shown in FIG. 2, the image display device 100 includes a plurality of LED modules 1001 to 1004 each being an image display module, and a housing frame 5. The housing frame 5 is a frame for retaining the plurality of LED modules 1001 to 1004. In the following description, when the LED modules 1001 to 1004 are not distinguished, each of the LED modules is referred to as an LEI) module 1000.

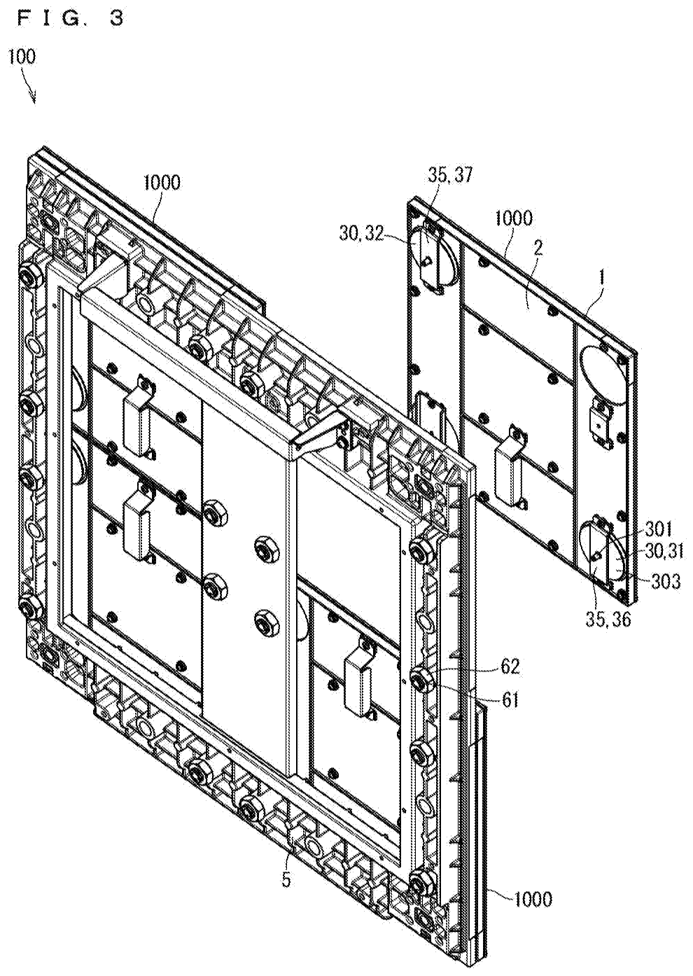

FIG. 3 is a perspective view showing a rear configuration of the image display device 100, with one LED module 1000 removed. The image display device 100 includes the LED modules 1000, fixing screw 31 and 32 (each referred to as a fixing screw 30 when not distinguished), retaining members 36 and 37 (each referred to as a retaining member 35 when not distinguished) each being a retainer, adjustment screws 61, fixing nuts 62, and other members such as screws. The LED module 1000 includes an LED board 1 on which LED elements being display elements are disposed to be mounted thereon, a mold base 2 for retaining the LED board 1, and other members such as screws.

The adjustment screw 61 and the fixing nut 62 fall under the concept of an adjustment unit. As in clear description given below, the adjustment unit adjusts positions of the LED modules 1000 in a direction perpendicular to the display screens of the LED modules 1000 while the LED modules 1000 are temporarily fixed to the housing frame 5. Through this adjustment, front surfaces of the LED modules 1001 to 1004 to be disposed on the image display device 100 can have uniform height, and level difference therebetween can be reduced. Note that, the adjustment screws 61 are turned during the adjustment.

The fixing screw 30 and the retaining member 35 fall under the concept of a fixing unit. As in clear description given below, the fixing unit fixes, to the housing frame 5, the LED modules 1000 that are temporarily fixed to the housing frame 5. Note that, the fixing screws 30 are turned during the fixing. Further, a turning axis of the adjustment screw 61 and a turning axis of the fixing screw 30 are arranged coaxially.

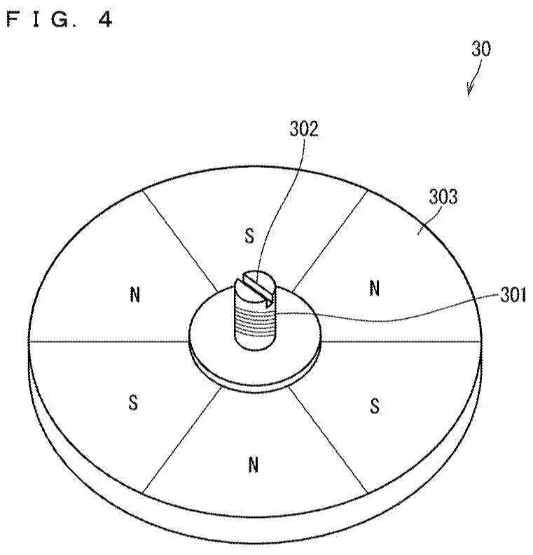

FIG. 4 is a perspective view showing a configuration of the fixing screw 30. The fixing screw 30 has a shank portion, and a side surface of the shank portion is provided with male threads 301 for fixing the LED modules to the housing frame side. One end of the shank portion of the fixing screw 30 is provided with a groove 302 for allowing a mechanical tool such as a driver to tighten the fixing screw 30. The other end of the shank portion of the fixing screw 30 is provided with a flange portion 303. The flange portion 303 includes a plurality of (six, in FIG. 4) magnets being a plurality of first magnets having different magnetic poles that are disposed in a turning direction of the fixing screw 30 (the male threads 301).

As shown in FIG. 3, the retaining members 35 being made of a magnetic material, such as a soft magnetic material, are fixed to the LED module 1000 by a screw or the like. The retaining member 35 turnably retains the fixing screw 30 while the retaining member 35 disposes the flange portion 303 including the plurality of magnets of the fixing screw 30 so as to be opposed to the LED module 1000 and exposes the male threads 301 and the groove 302 of the fixing screw 30. Note that, the fixing screw 30 is to be engaged with the adjustment screw 61.

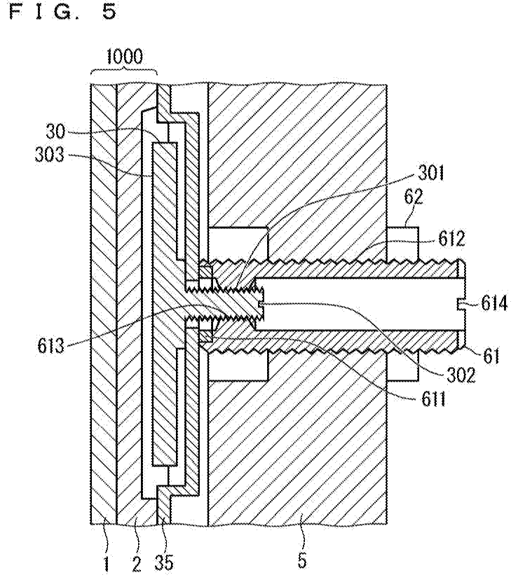

FIG. 5 is a cross-sectional view showing a structure of the adjustment unit and the fixing unit according to the first embodiment. The adjustment screw 61 has a hollow cylindrical shape. The adjustment screw 61 includes a magnet 611 being a second magnet, male threads 612 being a first threaded part, and female threads 613 being a second threaded part.

The magnet 611 is provided inside the cylinder of the adjustment screw 61 on the LED module 1000 side of the adjustment screw 61. The magnet 611 can be attracted to the retaining member 35 by a magnetic force, and can thereby temporarily fix the retaining member 35 and the adjustment screw 61.

An attracting force as the magnetic force of the magnet 611 is herein set to at least have strength capable of keeping one LED module 1000 onto the housing frame 5 at attachment positions using as many adjustment screws 61 as used for one LED module 1000. With this, the magnet 611 of the adjustment screw 61 can temporarily fix the LED module 1000 and the housing frame 5.

The male threads 612 are provided on an outer surface of the cylinder of the adjustment screw 61. The male threads 612 are engaged with the housing frame 5 while the retaining member 35 and the adjustment screw 61 are temporarily fixed and the adjustment screw 61 is freely movable in a direction perpendicular to the display screen of the LED module 1000.

One side of the adjustment screw 61 opposite to the LED module 1000 is proved with a groove 614 for allowing a mechanical tool such as a driver to tighten the adjustment screw 61. Turning the adjustment screw 61 using the groove 614, the adjustment screw 61 can be moved with respect to the housing frame 5 with the adjustment screw 61 penetrating the housing frame 5. That is, the adjustment screw 61 can be screwed toward the LED module 1000 side from the rear of the housing frame 5 while maintaining the above-mentioned temporary fixing.

The fixing nut 62 serves as a nut for preventing movement of the adjustment screw 61 with respect to the housing frame 5, further, movement thereof in a direction perpendicular to the display screen of the LED module 1000, and also serves as a nut for fixing the adjustment screw 61 to the housing frame 5.

Incidentally, even though the LED module 1000 is temporarily fixed to the housing frame 5, the LED module 1000 may be detached from the housing frame 5 if a force of separating the LED module 1000 from the housing frame 5 exceeds the attracting force of the magnet 611. Such detachment is convenient when intentional detachment is carried out, such as in a case of maintenance; however, there is a disadvantage in that positional displacement or falling of the LED module 1000 occurs in the event of an earthquake, for example.

In view of this, the fixing screw 30 is capable of fastening the temporarily fixed retaining member 35 and adjustment screw 61, that is, capable of fastening the temporarily fixed LED module 1000 and housing frame 5. Specifically, the female threads 613 are provided on an inner surface of the cylinder of the adjustment screw 61. The female threads 613 are engaged with the male threads 301 of the fixing screw 30 such that the fixing screw 30 fixes the temporarily fixed retaining member 35 and adjustment screw 61. Note that, the cylindrical adjustment screw 61 can expose the groove 302 of the fixing screw 30 that is engaged with the female threads 613.

<Procedures of Adjusting and Attaching/Detaching LED Module>

While the LED module 1000 is temporarily fixed by the magnet 611, a mechanical tool such as a driver is fitted into the groove 614 of the adjustment screw 61 from the rear, and the adjustment screw 61 is then turned. With this, the position of the LED module 1000 is adjusted so as to reduce level difference between display screens of the LED modules 1000 in the housing frame 5.

After the adjustment, the male threads 301 of the fixing screw 30 on the LED module 1000 side and the female threads 613 of the adjustment screw 61 on the housing frame 5 side are fastened with a screw. Then, the position of the adjustment screw 61 with respect to the housing frame 5 is fixed with the fixing nut 62. That is, the LED module 1000 and the housing frame 5 are fixed. Note that, a turning axis of the adjustment screw 61 and a turning axis of the fixing screw 30 are arranged coaxially.

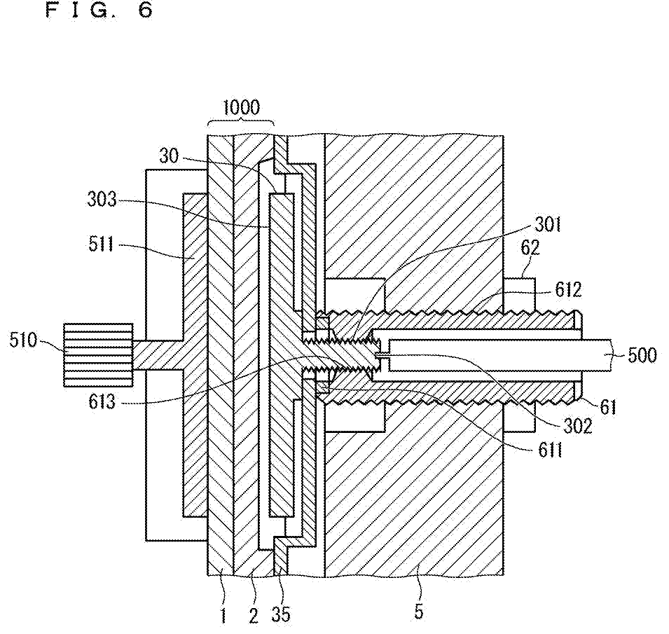

FIG. 6 is a cross-sectional view for illustrating the fixing of the fixing screw 30 in more detail.

When manufactured, the LED module 1000 is fixed as follows: a mechanical tool 500 such as a driver is fitted into the groove 302 of the fixing screw 30 from the rear of the multi-display system 200, and the fixing screw 30 is then turned.

In contrast, after the multi-display system 200 is installed, the LED module 1000 is attached and detached as follows: the fixing screw 30 is turned from the display screen side of the LED module 1000 using an attachment/detachment jig 510.

In this case, the attachment/detachment jig 510 has a flange portion 511 in which a plurality of magnets having different magnetic poles are disposed, similarly to the flange portion 303 of the fixing screw 30 of the LED module 1000. The flange portion 511 is opposed to the flange portion 303 of the fixing screw 30, thereby forming a magnetic coupling conjointly with the flange portion 303. With this, the fixing screw 30 can be turned by turning the flange portion 511 of the attachment/detachment jig 510, and the LED module 1000 can accordingly be attached and detached.

<Gist of First Embodiment>

Incidentally, an image display device in which a turning axis of an adjustment screw and a turning axis of a fixing screw are arranged at separate positions may cause displacement in adjustment positions when the LED module 1000 is fixed with a fixing unit after adjusting the position of the LED module 1000 with an adjustment unit.

Contrastingly, in the image display device 100 according to the first embodiment, a turning axis of the adjustment screw 61 and a turning axis of the fixing screw 30 are arranged coaxially. With such a configuration, displacement in adjustment positions can be reduced when the LED module 1000 is fixed after adjusting the position of the LED module 1000. Therefore, deflection in the LED module 1000, which is caused due to positional displacement between the turning axis of the adjustment screw 61 and the turning axis of the fixing screw 30, can be reduced.

Further, reducing deflection in the LED module 1000 can lead to reduction in stress applied to solder portions of components mounted on the LED board 1. Therefore, enhancement in reliability of the LED board 1 in long-term use can be expected.

Note that, deflection of an LED module 1000 in a case of reattaching the LED module 1000 during maintenance service etc. may cause repeated attaching operation a number of times in order to eliminate level difference between display screens of adjacent LED modules 1000. In the first embodiment, however, deflection during the fixing of the LED module 1000 can be reduced. Accordingly, the number of times of repetition of attaching operation can be decreased, and thus operation can be facilitated.

Further, since the first embodiment includes the adjustment unit, level difference between the display screens of the image display devices 100 can be reduced, and image quality can thereby be enhanced. In addition, since the LED module 1000 is fastened and fixed with the fixing screw 30, positional displacement and falling of the LED module 1000 that may be caused due to vibration such as that in an earthquake can be prevented after the multi-display system 200 is installed.

Further, in the first embodiment, the fixing screw 30 is retained by the retaining member while the flange portion 303 including a plurality of magnets of the fixing screw 30 is opposed to the LED module 1000. With such a configuration, the LED module 1000 can be attached and detached from the display screen side of the LED module 1000 using the attachment/detachment jig 510. With this, after the multi-display system 200 is installed, a maintenance space for a person need not be provided on the rear of the multi-display system 200, and therefore the installment space can be reduced.

Further, the retaining member 35 of the fixing screw 30 is made of a magnetic material. Therefore, the magnet of the fixing screw 30 is inclined to be attracted to the retaining member 35, and thereby the screw can be prevented from being loosened due to vibration or the like. Further, because the fixing screw 30 is maintained substantially perpendicularly to the LED module 1000 owing to the attracting force, the fixing screw 30 can be prevented from tilting in the gravity direction when the LED module 1000 is attached for use, which can enhance operability.

Further, in the first embodiment, since the adjustment screw 61 includes the magnet 611 for temporarily fixing the retaining member 35 and the adjustment screw 61, the position of the LED module 1000 can be comparatively easily adjusted.

Note that, in the first embodiment, as in FIG. 3, two fixing screws 30 are used to fix and adjust the position of the LED module 1000. However, the number of the fixing screws 30 need not necessarily be two, and may be changed as necessary.

Further, in the first embodiment, the image display device 100 includes four LED modules 1000. However, the number of LED modules of the image display device 100 is not restricted, and the number may be one, or may be eight, for example.

### Second Embodiment

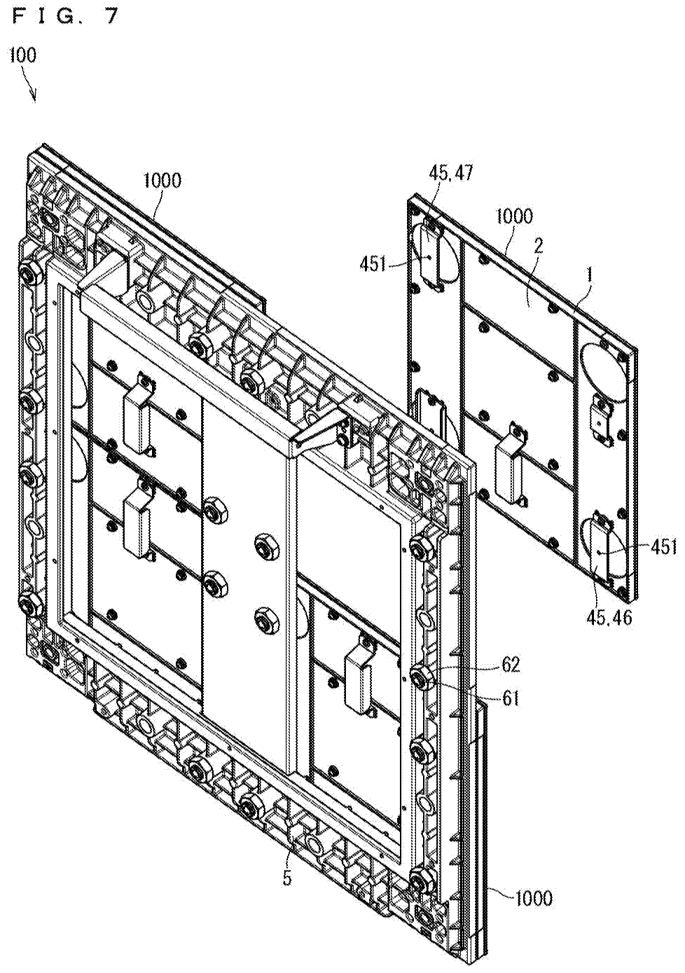

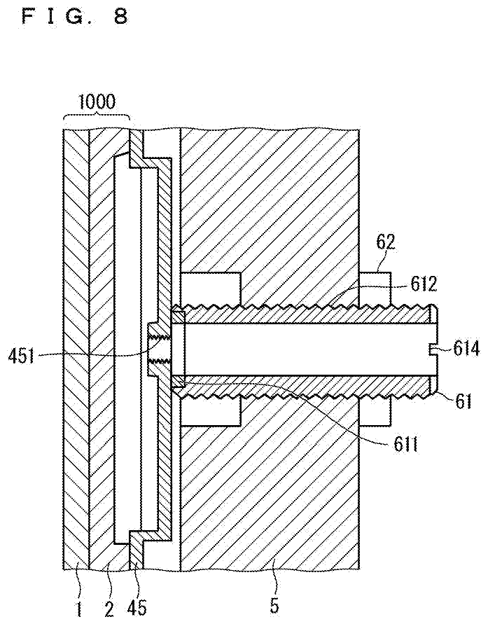

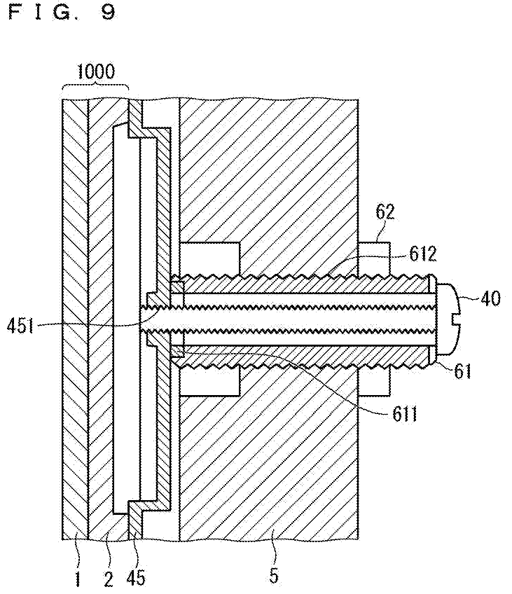

FIG. 7 is a perspective view showing a rear configuration of an image display device 100 according to a second embodiment of the present invention, similarly to FIG. 3. FIG. 8 is a cross-sectional view showing a structure of an adjustment unit and a fixing unit according to the second embodiment. FIG. 9 is a cross-sectional view for illustrating fixing of a usual fixing screw 40. In the following, among components according to the second embodiment, components that are identical or similar to the above-mentioned components are denoted by the same reference symbols, and different components will be mainly described.

The second embodiment is different from the first embodiment in that the LED module 1000 is fixed using a usual fixing screw 40 (FIG. 9), in place of the fixing screw 30 (FIG. 4) including the flange portion 303 having magnetic poles.

Similarly to the retaining members 35 (FIG. 3) according to the first embodiment, retaining members 46 and 47 (each referred to as a retaining member 45 when not distinguished) of FIG. 7 according to the second embodiment are made of a magnetic material such as a soft magnetic material, and are fixed to the LED module 1000 with a screw or the like. Note that, the retaining member 45 does not retain the fixing screw 40 turnably, but can be attached to and detached from the fixing screw 40.

Note that, the fixing screw 40 and the retaining member 45 fall under the concept of a fixing unit. The fixing unit fixes, to the housing frame 5, the LED modules 1000 that are temporarily fixed to the housing frame 5. Note that, the usual fixing screws 40 are turned during the fixing. Further, a turning axis of the adjustment screw 61 and a turning axis of the fixing screw 40 are arranged coaxially.

As shown in FIG. 8, the adjustment screw 61 has a hollow cylindrical shape. The adjustment screw 61 includes a magnet 611 being a magnet, and male threads 612 being a first threaded part. That is, the adjustment screw 61 according to the second embodiment is substantially the same as the adjustment screw 61 according to the first embodiment aside from the omission of the female threads 613 (FIG. 5).

The magnet 611 is provided inside the cylinder of the adjustment screw 61 on the LED module 1000 side of the adjustment screw 61. The magnet 611 can be attracted to the retaining member 45 by a magnetic force, and can thereby temporarily fix the retaining member 45 and the adjustment screw 61.

An attracting force as the magnetic force of the magnet 611 is herein set to at least have strength capable of keeping one LED module 1000 onto the housing frame 5 at attachment positions using as many adjustment screws 61 as used for one LED module 1000. With this, the magnet 611 of the adjustment screw 61 can temporarily fix the LED module 1000 and the housing frame 5.

The male threads 612 are provided on an outer surface of the cylinder of the adjustment screw 61. The male threads 612 are engaged with the housing frame 5 while the retaining member 45 and the adjustment screw 61 are temporarily fixed and the adjustment screw 61 is freely movable in a direction perpendicular to the display screen of the LED module 1000.

One side of the adjustment screw 61 opposite to the LED module 1000 is proved with a groove 614 for allowing a mechanical tool such as a driver to tighten the adjustment screw 61. With this, the adjustment screw 61 can be screwed toward the LED module 1000 side from the rear of the housing frame 5 while maintaining the above-mentioned temporary fixing.

While the LED module 1000 is temporarily fixed by the magnet 611, a mechanical tool such as a driver is fitted into the groove 614 of the adjustment screw 61 from the rear, and the adjustment screw 61 is then turned. With this, the position of the LED module 1000 is adjusted so as to reduce level difference between display screens of the LED modules 1000 in the housing frame 5. After the adjustment, the position of the adjustment screw 61 with respect to the housing frame 5 is fixed with a fixing nut 62.

As shown in FIG. 9, the retaining member 45 includes female threads 451 being a second threaded part to be engaged with the fixing screw 40. The cylindrical adjustment screw 61 can expose the female threads 451 of the retaining member 45. The fixing screw 40 is inserted into the adjustment screw 61 to be fastened to the female threads 451, thereby fixing the temporarily fixed retaining member 45 and adjustment screw 61. With this, the LED module 1000 and the housing frame 5 are fixed.

<Gist of Second Embodiment>

According to the image display device 100 of the second embodiment, similarly to the image display device 100 of the first embodiment, a turning axis of the adjustment screw 61 and a turning axis of the fixing screw 40 are arranged coaxially. Therefore, deflection of the LED module 1000 can be reduced.

Further, similarly to the first embodiment, since the adjustment unit is included, level difference between the display screens of the image display devices 100 can be reduced, and image quality can thereby be enhanced. Further, since the LED module 1000 is fastened and fixed with the fixing screw 40, positional displacement and falling of the LED module 1000 that may be caused due to vibration such as that in an earthquake can be prevented after the multi-display system 200 is installed.

Note that, also in the second embodiment, the number of the fixing screws 40 and the number of the LED modules of the image display device 100 are not limited to each number shown in FIG. 7 to FIG. 9, and may be changed as necessary.

Note that, in the present invention, each of the embodiments may be freely combined, and each of the embodiments may be modified or omitted as appropriate within the scope of the invention.

While the invention has been shown and described in detail, the foregoing description is in all aspects illustrative and not restrictive. It is therefore understood that numerous unillustrated modifications can be devised without departing from the scope of the invention.

### EXPLANATION OF REFERENCE SIGNS

5 housing frame, 30-32, 40 fixing screw, 35-37, 45-47 retaining member, 61 adjustment screw, 62 fixing nut, 100-106 image display device, 200 multi-display system, 302 groove, 611 magnet, 612 male thread, 451, 613 female thread, 1000-1004 LED module

1. An image display device comprising:
an image display module on which display elements are disposed;
a frame to which the image display module is to be fixed;
an adjustment unit that adjusts a position of the image display module in a direction perpendicular to a display screen of the image display module while the image display module is temporarily fixed to the frame; and
a fixing unit that fixes, to the frame, the image display module that is temporarily fixed to the frame, wherein
the adjustment unit comprises an adjustment screw that is turned during adjustment,
the fixing unit comprises a fixing screw that is turned during fixing, and
a turning axis of the adjustment screw and a turning axis of the fixing screw are arranged coaxially.

2. The image display device according to claim 1, wherein
one end of the fixing screw is provided with a groove used for tightening the fixing screw,
another end of the fixing screw is provided with a plurality of first magnets having different magnetic poles that are disposed in a turning direction of the fixing screw,
the fixing unit further comprises a retainer made of a magnetic material and fixed to the image display module, and
the retainer turnably retains the fixing screw while the retainer disposes the plurality of first magnets of the fixing screw so as to be opposed to the image display module and exposes the groove of the fixing screw.

3. The image display device according to claim 2, wherein
the adjustment screw comprises:
a second magnet that temporarily fixes the retainer and the adjustment screw;
a first threaded part to be engaged with the frame while the retainer and the adjustment screw are temporarily fixed and the adjustment screw is freely movable in a direction perpendicular to the display screen of the image display module; and
a second threaded part to be engaged with the fixing screw such that the fixing screw fixes the retainer and the adjustment screw, and
the adjustment screw has a hollow shape so as to expose the groove of the fixing screw that is engaged with the second threaded part.

4. The image display device according to claim 1, wherein
one end of the fixing screw is provided with a groove used for tightening the fixing screw,
the fixing unit further comprises a retainer made of a magnetic material and fixed to the image display module,
the retainer turnably retains the fixing screw while the retainer exposes the groove of the fixing screw,
the adjustment screw comprises:
a magnet that temporarily fixes the retainer and the adjustment screw;
a first threaded part to be engaged with the frame while the retainer and the adjustment screw are temporarily fixed and the adjustment screw is freely movable in a direction perpendicular to the display screen of the image display module; and
a second threaded part to be engaged with the fixing screw such that the fixing screw fixes the retainer and the adjustment screw, and
the adjustment screw has a hollow shape so as to expose the groove of the fixing screw that is engaged with the second threaded part.

5. The image display device according to claim 1, wherein
the fixing unit further comprises a retainer made of a magnetic material and fixed to the image display module,
the adjustment screw comprises:
a magnet that temporarily fixes the retainer and the adjustment screw; and
a first threaded part to be engaged with the frame while the retainer and the adjustment screw are temporarily fixed and the adjustment screw is freely movable in a direction perpendicular to the display screen of the image display module,
the retainer comprises a second threaded part to be engaged with the fixing screw such that the fixing screw fixes the retainer and the adjustment screw, and
the adjustment screw has a hollow shape so as to expose the second threaded part of the retainer.

6. The image display device according to claim 1, wherein
the adjustment unit further comprises a fixing nut that fixes the adjustment screw to the frame.

7. A multi-display system comprising a plurality of the image display devices of claim 1.
